(19) United States
(12) Patent Application Publication
(10) Pub. No.: US 2025/0260254 A1
(43) Pub. Date: Aug. 14, 2025

(54) POWER SUPPLY CIRCUIT HAVING BACK-TO-BACK TRANSISTORS WITH SEPARATE GATE CONTROL AND/OR SEPARATE CURRENT SENSING

(71) Applicant: QUALCOMM Incorporated, San Diego, CA (US)

(72) Inventors: Jiwei CHEN, San Jose, CA (US); Xinying DING, Cupertino, CA (US); Guoyong GUO, San Jose, CA (US)

(21) Appl. No.: 18/442,003

(22) Filed: Feb. 14, 2024

(51) Int. Cl. H02J 7/00; H02M 1/00; H02M 3/158

(52) U.S. Cl. CPC H02J 7/00714; H02J 7/007182; H02M 1/0045; H02M 3/158

(57) ABSTRACT

Certain aspects of the present disclosure provide techniques and apparatus for supplying power, including battery charging. One example power supply circuit generally includes a switching regulator including an output node coupled to a power supply node, a battery node for coupling to a battery, a first transistor including a drain coupled to the power supply node, a second transistor including a source coupled to a source of the first transistor and a drain coupled to the battery node, a first current sense circuit coupled to the drain of the first transistor, and a second current sense circuit coupled to the drain of the second transistor.

### TECHNICAL FIELD

Certain aspects of the present disclosure generally relate to power supply circuits and, more particularly, to techniques and apparatus for controlling the gates of back-to-back transistors included in a power supply circuit, such as a battery charger.

### BACKGROUND

A voltage regulator ideally provides a constant direct current (DC) output voltage regardless of changes in load current or input voltage. Voltage regulators may be classified as linear regulators or switching regulators. While linear regulators tend to be relatively compact, many applications may benefit from the increased efficiency of a switching regulator. A linear regulator may be implemented by a low-dropout (LDO) regulator, for example. A switching regulator (also known as a “switching converter” or “switcher”) may be implemented, for example, by a switched-mode power supply (SMPS), such as a buck converter, a boost converter, a buck-boost converter, or a charge pump.

For example, a buck converter is a type of SMPS typically comprising: (1) a high-side switch coupled between a relatively higher voltage rail and a switching node, (2) a low-side switch coupled between the switching node and a relatively lower voltage rail, (3) and an inductor coupled between the switching node and a load (e.g., represented by a shunt capacitive element). The high-side and low-side switches are typically implemented with transistors, although the low-side switch may alternatively be implemented with a diode.

A charge pump is a type of SMPS typically comprising at least one switching device to control the connection of a supply voltage across a load through a capacitor. In a voltage doubler (also referred to as a “multiply-by-two (X2) charge pump”), for example, the capacitor of the charge pump circuit may initially be connected across the supply, charging the capacitor to the supply voltage. The charge pump circuit may then be reconfigured to connect the capacitor in series with the supply and the load, doubling the voltage across the load. This two-stage cycle is repeated at the switching frequency for the charge pump. Charge pumps may be used to multiply or divide voltages by integer or fractional amounts, depending on the circuit topology.

Power management integrated circuits (power management ICs or PMICs) are used for managing the power scheme of a host system and may include and/or control one or more voltage regulators (e.g., buck converters or charge pumps). A PMIC may be used in battery-operated devices, such as mobile phones, tablets, laptops, wearables, etc., to control the flow and direction of electrical power in the devices. The PMIC may perform a variety of functions for the device such as DC-to-DC conversion (e.g., using a voltage regulator as described above), battery charging, power-source selection, voltage scaling, power sequencing, etc.

### SUMMARY

The systems, methods, and devices of the disclosure each have several aspects, no single one of which is solely responsible for its desirable attributes. Without limiting the scope of this disclosure as expressed by the claims that follow, some features are discussed briefly below. After considering this discussion, and particularly after reading the section entitled “Detailed Description,” one will understand how the features of this disclosure provide the advantages described herein.

Certain aspects of the present disclosure provide a power supply circuit. The power supply circuit generally includes a switching regulator including an output coupled to a power supply node; a battery node for coupling to a battery; a first transistor including a drain coupled to the power supply node; a second transistor including a source coupled to a source of the first transistor and a drain coupled to the battery node; a first current sense circuit coupled to the drain of the first transistor; and a second current sense circuit coupled to the drain of the second transistor.

Certain aspects of the present disclosure provide an integrated circuit. The integrated circuit generally includes the power supply circuit described herein.

Certain aspects of the present disclosure provide a device. The device generally includes a switching regulator including an output node coupled to a power supply node; a battery coupled to a battery node; a first transistor including a drain coupled to the power supply node; a second transistor including a source coupled to a source of the first transistor and a drain coupled to the battery node; a first sense circuit coupled to the drain of the first transistor; and a second current sense circuit coupled to the drain of the second transistor.

Certain aspects of the present disclosure are directed to a method of supplying power. The method generally includes: sensing a current through one of a first transistor and a second transistor, the first transistor including a drain coupled to a power supply node, the second transistor including a drain coupled to a battery, and the second transistor further including a source coupled to a source of the first transistor; and controlling a charging current flowing to the battery or a discharging current flowing from the battery by adjusting at least one of a gate voltage of the first transistor or a gate voltage of the second transistor based on the sensed current.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device comprising a power management system that includes a power management integrated circuit (PMIC) and a battery charging circuit, in which aspects of the present disclosure may be practiced.

FIG. 2 is a circuit diagram of an example power supply circuit, in accordance with certain aspects of the present disclosure.

FIG. 3 is a circuit diagram of an example power supply circuit, in accordance with certain aspects of the present disclosure.

FIG. 4A is a circuit diagram of a portion of an example power supply circuit including back-to-back transistors having independent gate control circuits and independent current sense circuits, in accordance with certain aspects of the present disclosure.

FIG. 4B is a circuit diagram of the portion of the power supply circuit of FIG. 4A operating to accommodate a first example use case, in accordance with certain aspects of the present disclosure.

FIG. 4C is a circuit diagram of the portion of the power supply circuit of FIG. 4A operating to accommodate a second example use case, in accordance with certain aspects of the present disclosure.

FIG. 5 is a circuit diagram of a portion of an example power supply circuit including back-to-back transistors and a gate control circuit for controlling operation of the transistors in a first example mode, in accordance with certain aspects of the present disclosure.

FIG. 6 is a circuit diagram of a portion of an example power supply circuit including back-to-back transistors and a gate control circuit for controlling operation of the transistors in a second example mode, in accordance with certain aspects of the present disclosure.

FIG. 7 is a flow diagram of example operations for supplying power, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for controlling the current flow between a battery and a power supply rail using a power supply circuit that includes a switching regulator and an electrical path (e.g., for charging/discharging the battery) that includes back-to-back transistors. The power supply circuit further includes one or more control circuits for controlling the gate voltages of the back-to-back transistors and current sense circuits for sensing current through the back-to-back transistors, to accommodate different use cases, such as a first use case (e.g., linear charging) in which the battery is charged and a second use case (e.g., soft start) in which the power supply rail voltage is increased. In particular, the gate voltages of the back-to-back transistors may be regulated during different charging and discharging phases in which the battery current may vary, yet should still be accurate.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatus, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

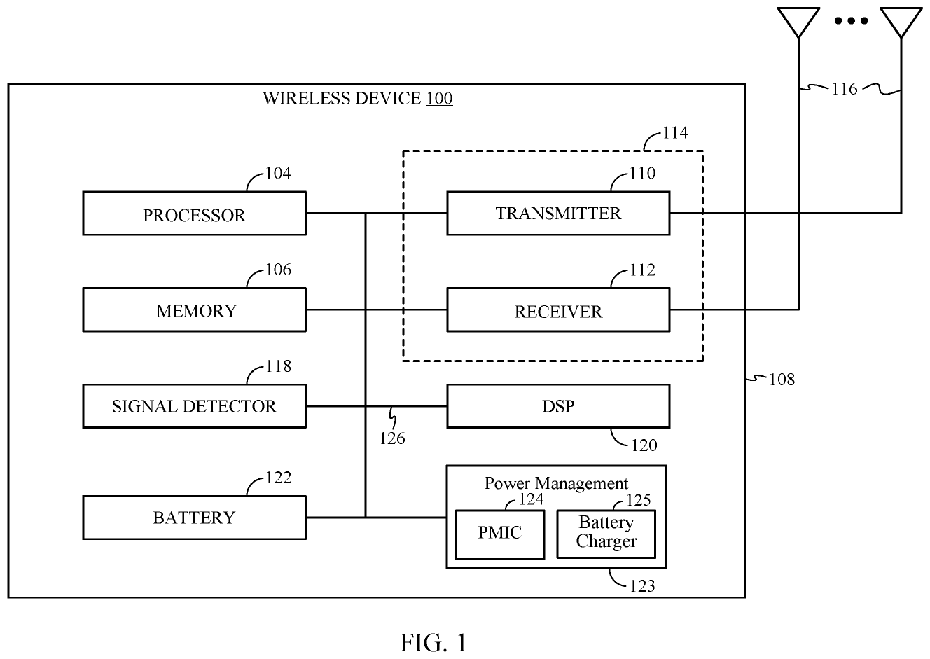

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an Internet of things (IoT) device, a wearable device, etc. For certain aspects, the device 100 may be a foldable device (e.g., a flip phone).

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when another power source-such as a wall adapter or a wireless power charger—is unavailable). The battery 122 may comprise a single cell or multiple cells connected in series and/or in parallel. The device 100 may further include additional independent batteries (not shown). Each of the additional independent batteries may comprise a single cell or multiple cells connected in series and/or in parallel.

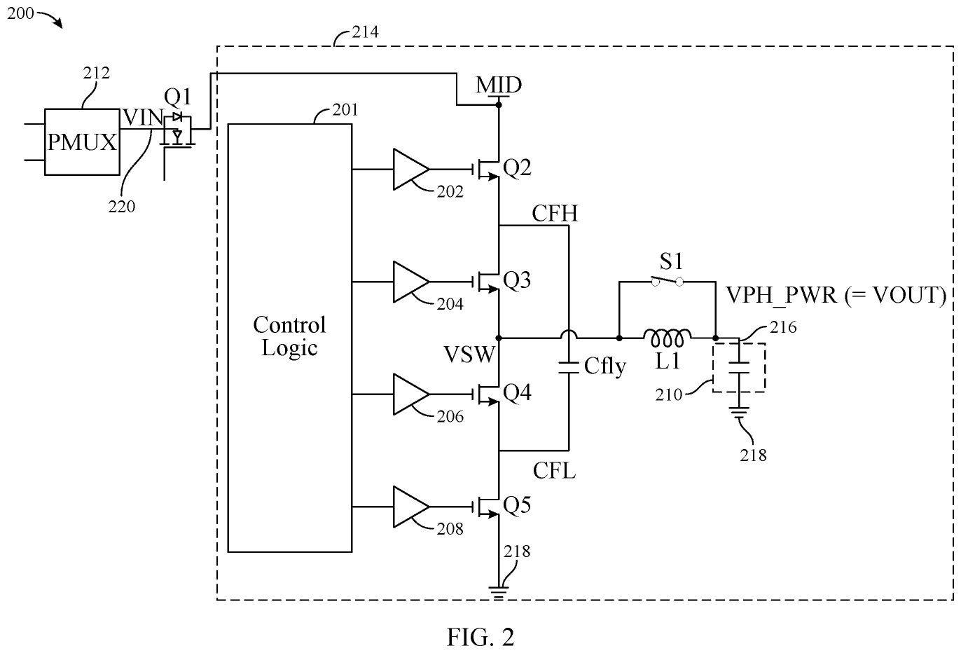

The device 100 may also include a power management system 123 for managing the power from the battery 122 (or batteries), a wall adapter, and/or a wireless power charger to the various components of the device 100. The power management system 123 may perform a variety of functions for the device such as DC-to-DC conversion, battery charging, power-source selection, voltage scaling, power sequencing, source mode power, etc. In certain aspects, the power management system 123 may include a power management integrated circuit (power management IC or PMIC) 124 and one or more power supply circuits, such as a battery charger 125, which may be controlled by the PMIC or logic associated with the battery charger, for example. For certain aspects, at least a portion of one or more of the power supply circuits (e.g., at least a portion of the battery charger 125) may be integrated in the PMIC 124. The PMIC 124 and/or the one or more power supply circuits may include at least a portion of a switched-mode power supply (SMPS) circuit, which may be implemented by any of various suitable switched-mode power supply circuit topologies, such as a two-level buck converter, a three-level buck converter, a charge pump, or an adaptive combination power supply circuit (e.g., the SMPS circuit 214 of FIG. 2), which can switch between operating in a buck converter mode and a charge pump mode, as described below.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Power Supply Circuits and Operation

As described above, the PMIC 124 and/or the one or more power supply circuits (e.g., battery charger 125) may include at least a portion of an SMPS circuit (e.g., a buck converter, a charge pump converter, or an adaptive combination power supply circuit capable of switching therebetween), which may be a single-phase or multi-phase converter. In the case of an adaptive combination power supply circuit, both converter modes may be single-phase, both converter modes may be multi-phase, one converter mode may be single-phase while the other converter mode is multi-phase or capable of changing between single-phase and multi-phase, or one converter mode may be multi-phase while the other converter mode is capable of changing between single-phase and multi-phase.

FIG. 2 is a circuit diagram of an example power supply circuit 200, which may be used to charge one or more batteries. As illustrated, the power supply circuit 200 includes a power multiplexer 212 (labeled “PMUX”), a reverse-current-blocking transistor Q1 (which may also be referred to as an overvoltage protection (OVP) field-effect transistor (FET) or an input FET), and an SMPS circuit 214 (e.g., an adaptive SMPS circuit).

The power multiplexer 212 may be configured to select between receiving power from, for example, (i) a Universal Serial Bus (USB) port for connecting to a wall adapter and (ii) a wireless power port (both not shown). The power multiplexer 212 may be implemented as a single-pole, double-throw (SPDT) switch by two OVP FETs, and in this case, transistor Q1 may be eliminated.

In certain aspects, the output of the power multiplexer 212 may be coupled to an input voltage node 220 (labeled “VIN”). The input voltage node 220 may be coupled to a source of the transistor Q1, and a drain of the transistor Q1 may be coupled to a voltage node (labeled “MID”) of the SMPS circuit 214. The MID voltage node may serve as the power supply rail of the SMPS circuit 214, and in some cases, may alternatively be considered as an input node of the SMPS circuit. In some cases, the power multiplexer 212 and/or transistor Q1 may be removed.

For certain aspects, the SMPS circuit 214 may have a two-level buck converter topology. For other aspects, the SMPS circuit 214 may have a single-phase three-level buck converter topology (as illustrated in the power supply circuit 200 of FIG. 2), and may include a second transistor Q2, a third transistor Q3, a fourth transistor Q4, a fifth transistor Q5, a flying capacitive element Cfly, an inductive element L1, and a load 210 (e.g., represented as by a capacitor). For other aspects, the SMPS circuit 214 may have a dual-phase three-level buck converter topology. To realize an adaptive SMPS circuit, a switch S1 may be added across the inductive element L1 of the three-level buck converter topology. With the switch S1 closed, the adaptive SMPS circuit may function as a single-phase divide-by-two (Div2) charge pump converter, as further described below. In certain aspects, switch S1 may be implemented by two back-to-back transistors.

Transistor Q3 may be coupled to transistor Q2 via a first node (labeled “CFH” for flying capacitor high node), transistor Q4 may be coupled to transistor Q3 via a second node (labeled “VSW” for voltage switching node), and transistor Q5 may be coupled to transistor Q4 via a third node (labeled “CFL” for flying capacitor low node). For certain aspects, the transistors Q2-Q5 may be implemented as n-type metal-oxide-semiconductor (NMOS) transistors, as illustrated in FIG. 2. In this case, the drain of transistor Q3 may be coupled to the source of transistor Q2, the drain of transistor Q4 may be coupled to the source of transistor Q3, and the drain of transistor Q5 may be coupled to the source of transistor Q4. The source of transistor Q5 may be coupled to a reference potential node 218 (e.g., electric ground) for the power supply circuit 200. The flying capacitive element Cfly may have a first terminal coupled to the first node and a second terminal coupled to the third node. The inductive element L1 may have a first terminal coupled to the second node and a second terminal coupled to an output voltage node 216 (labeled “VOUT,” which may also be referred to as “VPH_PWR,” “VPH,” or “VSYS” or may be coupled to a power supply rail referred to by these names) and the load 210.

Control logic 201 may control operation of the SMPS circuit 214 and other aspects of the power supply circuit 200. For example, the control logic 201 may control operation of the transistors Q2-Q5 via output signals to the inputs of respective gate drivers 202, 204, 206, and 208. The outputs of the gate drivers 202, 204, 206, and 208 are coupled to respective gates of transistors Q2-Q5. During operation of the adaptive SMPS circuit (or of a three-level buck converter), the control logic 201 may cycle through four different phases, which may differ depending on whether the duty cycle is less than 50% or greater than 50%.

Operation of the adaptive SMPS circuit with a duty cycle of less than 50% is described first. In a first phase (referred to as a “charging phase”), transistors Q2 and Q4 are activated, and transistors Q3 and Q5 are deactivated, to charge the flying capacitive element Cfly and to energize the inductive element L1. In a second phase (called a “holding phase”), transistor Q2 is deactivated, and transistor Q5 is activated, such that the VSW node is coupled to the reference potential node, the flying capacitive element Cfly is disconnected (e.g., one of the Cfly terminals is floating), and the inductive element L1 is deenergized. In a third phase (referred to as a “discharging phase”), transistors Q3 and Q5 are activated, and transistor Q4 is deactivated, to discharge the flying capacitive element Cfly and to energize the inductive element L1. In a fourth phase (also referred to as a “holding phase”), transistor Q4 is activated, and transistor Q3 is deactivated, such that the flying capacitive element Cfly is disconnected and the inductive element L1 is deenergized.

Operation of the adaptive SMPS circuit with a duty cycle greater than 50% is similar in the first and third phases, with the same transistor configurations. However, in the second phase (called a “holding phase”) following the first phase, transistor Q4 is deactivated, and transistor Q3 is activated, such that the VSW node is coupled to the MID node, the flying capacitive element Cfly is disconnected, and the inductive element L1 is energized. Similarly in the fourth phase (also referred to as a “holding phase”) with a duty cycle greater than 50%, transistor Q2 is activated, and transistor Q5 is deactivated, such that the flying capacitive element Cfly is disconnected and the inductive element L1 is energized.

Furthermore, the control logic 201 may have a control signal (not shown in FIG. 2) configured to control operation of switch S1 and selectively enable divide-by-two (Div2) charge pump operation. For certain aspects, when this control signal is logic low, switch S1 is open, and the power supply circuit 200 operates as a three-level buck converter using the inductive element L1. When this control signal is logic high for certain aspects, switch S1 is closed, thereby shorting across the inductive element L1 and effectively removing the inductive element L1 from the circuit, such that the adaptive SMPS circuit operates as a Div2 charge pump. The control logic 201 may be configured to automatically control operation of switch S1 (e.g., through the logic level of the control signal) based on an output current (also referred to as a “load current”) and/or an input current for the adaptive SMPS circuit.

### Example Power Supply Circuits for Battery Charging/Discharging

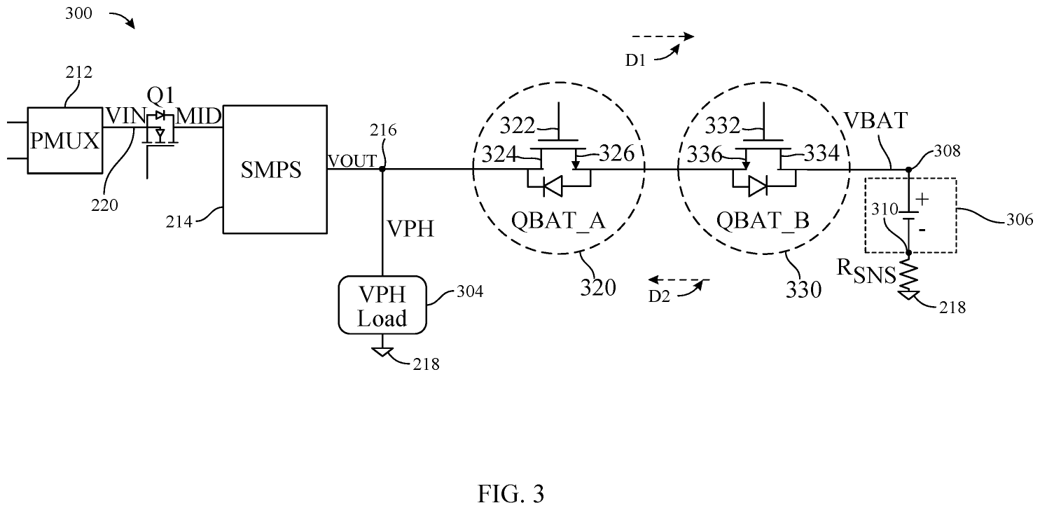

FIG. 3 is a circuit diagram of an example power supply circuit 300. The power supply circuit 300 may include the power multiplexer 212, the transistor Q1, and the SMPS circuit 214 (or another suitable SMPS circuit). The output node 216 of the SMPS circuit 214 may be coupled to (or may also serve as) a power supply node (e.g., labeled “VPH”). The power supply node VPH may be coupled and provide power to a load 304 (e.g., labeled “VPH load”). The load 304 may be analogous to the load 210 of FIG. 2. For example, the load 304 may represent one or more circuits of a device (e.g., the device 100 of FIG. 1) that are powered internally by the switching regulator (e.g., with power supply node VPH=VOUT). In some instances, the load 304 may be coupled (in shunt) to the reference potential node 218.

The power supply circuit 300 may include a battery node (labeled “VBAT”) for coupling to a battery 306. As shown, the battery 306 includes a first terminal 308 (e.g., positive electrode) coupled to the battery node VBAT and a second terminal 310 (e.g., negative electrode), which may be coupled to the reference potential node 218. In some instances, a sense resistive element R_{SNS} may be coupled between the reference potential node 218 and the second terminal 310 of the battery 306.

The power supply circuit 300 may include a first transistor 320 (labeled “QBAT_A”) and a second transistor 330 (labeled “QBAT_B”). The first transistor 320 includes a gate 322, a drain 324, and a source 326. Likewise, the second transistor 330 includes a gate 332, a drain 334, and a source 336. As shown, the drain 324 of the first transistor 320 is coupled to the power supply node VPH, and the drain 334 of the second transistor 330 is coupled to the battery node VBAT. Furthermore, the source 336 of the second transistor 330 is coupled to the source 326 of the first transistor 320. In this manner, an electrical path is provided between the power supply node VPH and the battery node VBAT. Furthermore, the first transistor 320 and the second transistor 330 may function to allow current to flow along the electrical path in a first direction (labeled “D1”) to charge the battery 306 or, alternatively, a second direction (labeled “D2”) to power the load 304 from the battery 306, thereby discharging the battery 306.

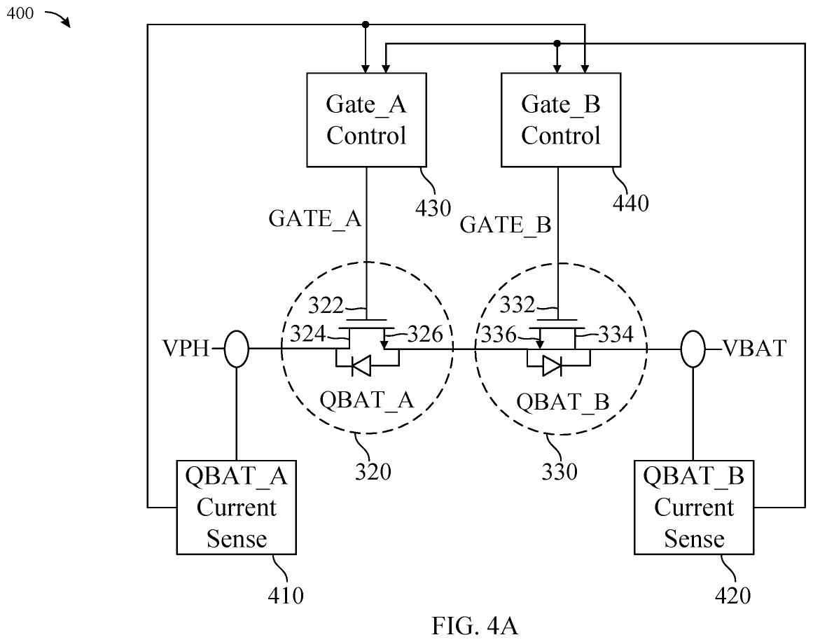

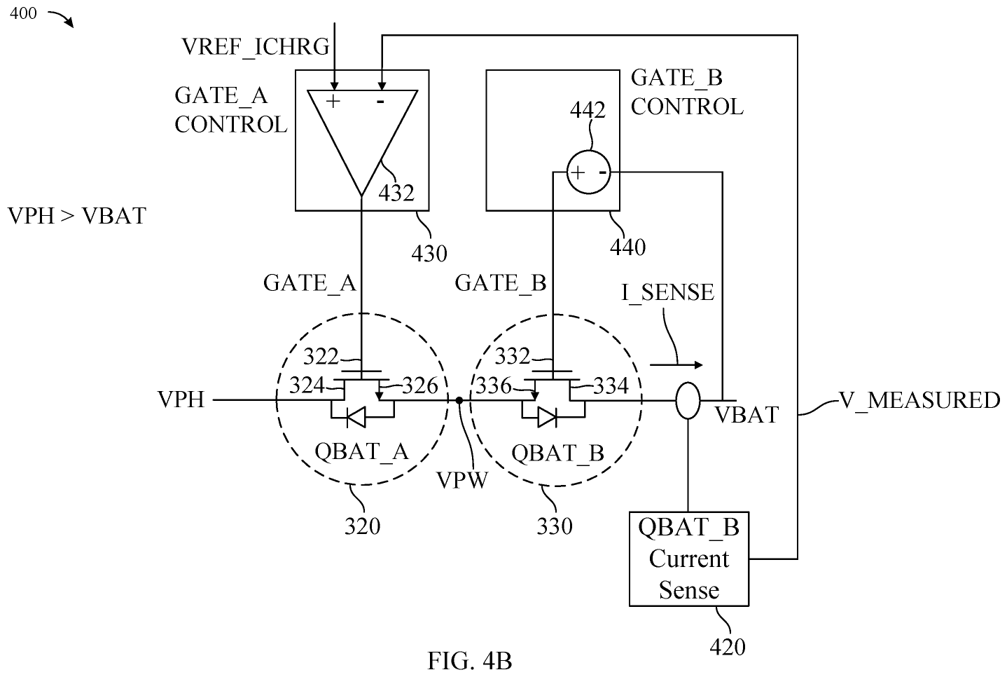

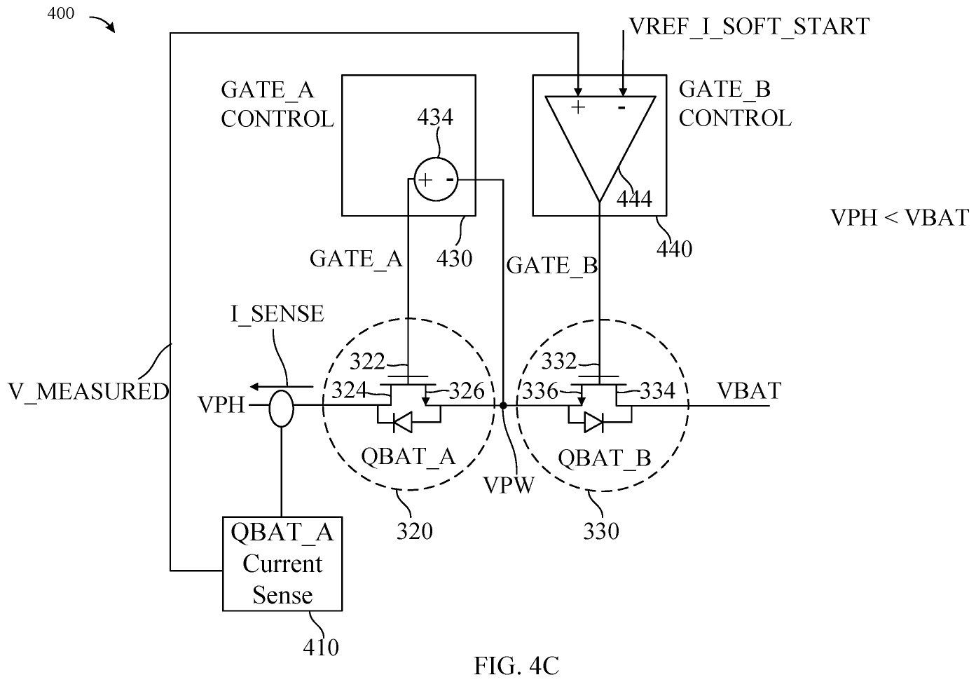

FIG. 4A depicts a portion of an example power supply circuit 400 in accordance with certain aspects of the present disclosure. The power supply circuit 400 includes the first transistor 320 and the second transistor 330 of the power supply circuit 300 discussed above with reference to FIG. 3. In addition, the power supply circuit 400 includes a first current sense circuit 410 coupled to the drain 324 of the first transistor 320 and a second current sense circuit 420 coupled to the drain 334 of the second transistor 330. In some instances, the first current sense circuit 410 and the second current sense circuit 420 may each include a sensor that can be enabled (e.g., powered on) and deactivated (e.g., powered off) via a control signal. In certain aspects, the first current sense circuit 410 and/or the second current sense circuit 420 may be implemented by a transistor in parallel with the respective first transistor 320 and/or second transistor 330.

The power supply circuit 400 may independently control operation of the first transistor 320 and the second transistor 330. For instance, the power supply circuit 400 includes a first control circuit 430 (e.g., labeled “Gate_A Control”) for controlling operation of the first transistor 320 and a second control circuit 440 (e.g., labeled “Gate_B Control”) for controlling operation of the second transistor 330.

In some instances, the first control circuit 430 and the second control circuit 440 may each include a first input coupled to an output of the first current sense circuit 410 and a second input coupled to an output of the second current sense circuit 420, as illustrated. In this manner, the first control circuit 430 and the second control circuit 440 may each receive a first current obtained (e.g., sensed) by the first current sense circuit 410 and a second current obtained by the second current sense circuit 420.

The first control circuit 430 and the second control circuit 440 may each include an output. For instance, the output of the first control circuit 430 may be coupled to the gate 322 of the first transistor 320, and the output of the second control circuit 440 may be coupled to the gate 332 of the second transistor 330. As will now be discussed, the first control circuit 430 and the second control circuit 440 may independently control operation of the first transistor 320 and the second transistor 330, respectively, to accommodate different uses of the power supply circuit 400.

FIG. 4B illustrates the portion of the power supply circuit 400 configured for a first use case (e.g., linear battery charging) in which a voltage at the power supply node VPH is greater than a voltage at the battery node VBAT. This may occur when an external power source (e.g., a wall adapter or a wireless charger) is being provided to a device (e.g., device 100) with the power supply circuit. Accordingly, for the first use case, the power supply circuit 400 may provide a charging current to a battery (e.g., the battery 306 of FIG. 3) coupled to the battery node VBAT, via the switching regulator (e.g., the SMPS circuit 214). In this manner, the battery may be charged (e.g., via the charging current).

For the first use case of the power supply circuit 400, the first current sense circuit 410 (FIG. 4A) may be disabled (e.g., turned off) for current sensing, and the second current sense circuit 420 may be enabled (e.g., turned on) for current sensing. As shown, the second current sense circuit 420 may obtain (e.g., sense) a current (e.g., labeled “I_SENSE”) and convert the current to a measured output voltage (e.g., labeled as “V_MEASURED”) that may be provided to the first control circuit 430.

The first control circuit 430 may control the first transistor 320 such that the first transistor 320 operates in a first mode (e.g., a linearly-on mode, also referred to as the linear region of the transistor) while the power supply circuit 400 is being used for the first use case (e.g., linear charging). For instance, the first control circuit 430 may include an amplifier 432. The amplifier 432 may include a first input coupled to the output of the second current sense circuit 420. In this manner, the first input of the amplifier 432 may receive the measured output voltage V_MEASURED. The amplifier 432 may also include a second input coupled to a reference voltage node. For example, the reference voltage node may be provided with a reference voltage associated with the first use case. In this manner, the second input of the amplifier 432 may receive the reference voltage (e.g., labeled as “VREF_ICHRG” for a reference voltage associated with a battery charging current).

The amplifier 432 may drive the gate 322 of the first transistor 320 with a control signal based, at least in part, on the difference between the reference voltage V_REF_ICHRG and the measured output voltage V_MEASURED. The control signal may regulate a gate voltage of the first transistor 320 to adjust the drain-to-source resistance thereof, thereby controlling the charging current flowing from the power supply node VPH to the battery node VBAT to a desired value (e.g., according to the reference voltage V_REF_ICHRG).

The second control circuit 440 may control the second transistor 330 such that the second transistor 330 operates in a second mode (e.g., a fully-on mode, also referred to as the saturation region of the transistor) that is different from the first mode (e.g., the linearly-on mode). As shown, the second control circuit 440 may include a constant voltage source 442. The voltage source 442 may be coupled between the battery node VBAT and the gate 332 of the second transistor 330. The voltage source 442 may be configured to keep the gate voltage of the second transistor 330 constant relative to a voltage at the battery node VBAT or a voltage at an intermediate node (labeled “VPW”) coupled to the source 326 of the first transistor 320 and the source 336 of the second transistor 330.

In some instances, the voltage source 442 may be implemented by a charge pump configured to generate a voltage (e.g., about 5 V). In such instances, the voltage generated by the constant voltage source 442 may be a sum of the voltage generated by the charge pump and a voltage the battery node VBAT or the intermediate node VPW.

In the first configuration or use case (e.g., linear charging), the current I_SENSE is effectively obtained by the second current sense circuit 420 that is coupled to the drain 334 of the second transistor 330 which, as mentioned above, is operating in the second mode (e.g., the fully-on mode). This is because the current sensing of the first current sense circuit 410 would be less accurate since the first transistor 320 is operating in the first mode (e.g., the linearly-on mode). In addition, the current flowing from the power supply node VPH to the battery node VBAT is regulated by the first transistor 320 which, as mentioned above, is operating in the first mode (e.g., the linearly-on mode).

FIG. 4C illustrates the portion of the power supply circuit 400 configured for a second use case (e.g., soft start of a voltage at the power supply node VPH) in which a voltage at the power supply node VPH is less than a voltage at the battery node VBAT. This may occur when a device (e.g., device 100 of FIG. 1) is initially turned on and an external power source is not available. Accordingly, for the second use case, the power supply circuit 400 may be used to discharge the battery (e.g., the battery 306 of FIG. 3) coupled to the battery node VBAT in a controlled manner to deliver a current to a load (e.g., the load 304 of FIG. 3) coupled to the power supply node VPH. In this manner, the battery may be discharged to power the load.

For the second use case of the power supply circuit 400, the first current sense circuit 410 (FIG. 4A) may be enabled (e.g., turned on) for current sensing, and the second current sense circuit 420 may be disabled (e.g., turned off) for current sensing. The first current sense circuit 410 may obtain (e.g., sense) a current (labeled “I_SENSE”) and convert the current to a measured output voltage (e.g., labeled as “V_MEASURED”).

The first control circuit 430 may control the first transistor 320 such that the first transistor 320 operates in the second mode (e.g., the fully-on mode). As shown, the first control circuit 430 may include a voltage source 434. The voltage source 434 may be coupled between the intermediate node VPW and the gate 322 of the first transistor 320. The voltage source 434 may be configured to keep the gate voltage of the first transistor 320 constant relative to a voltage at the power supply node VPH or the intermediate node VPW.

In some instances, the voltage source 434 may be implemented by a charge pump configured to generate a voltage (e.g., about 5 V). In such instances, the voltage generated by the constant voltage source 434 may be a sum of the voltage generated by the charge pump and a voltage at the power supply node VPH or the intermediate node VPW.

The second control circuit 440 may control the second transistor 330 such that the second transistor 330 operates in the first mode (e.g., the linearly-on mode). For instance, the second control circuit 440 may include an amplifier 444. The amplifier 444 may include a first input coupled to the output of the first current sense circuit 410. In this manner, the first input of the amplifier 444 may receive the measured output voltage V_MEASURED. The amplifier 444 may also include a second input coupled to a reference voltage node. In this manner, the second input of the amplifier 444 may receive a reference voltage (e.g., labeled as “VREF_I_SOFT_START” for a reference voltage associated with a soft start current).

The amplifier 444 may drive the gate 332 of the second transistor 330 with a control signal based, at least in part, on the difference between the reference voltage V_REF_I_SOFT_START and the measured output voltage V_MEASURED. The control signal may regulate a gate voltage of the second transistor 330 to adjust the current flowing from the battery node VBAT to the power supply node VPH to a desired value (e.g., according to the reference voltage V_REF_I_SOFT_START).

In the second configuration or use case (e.g., soft start), the current I_SENSE is effectively obtained by the first current sense circuit 410 that is coupled to the drain 324 of the first transistor 320 which, as mentioned above, is operating in the second mode (e.g., the fully-on mode). This is because the current sensing of the second current sense circuit 420 would be less accurate since the second transistor 330 is operating in the first mode (e.g., the linearly-on mode). In addition, the current flowing from the battery node VBAT to the power supply node VPH is regulated by the second transistor 330 which, as mentioned above, is operating in the first mode (e.g., the linearly-on mode).

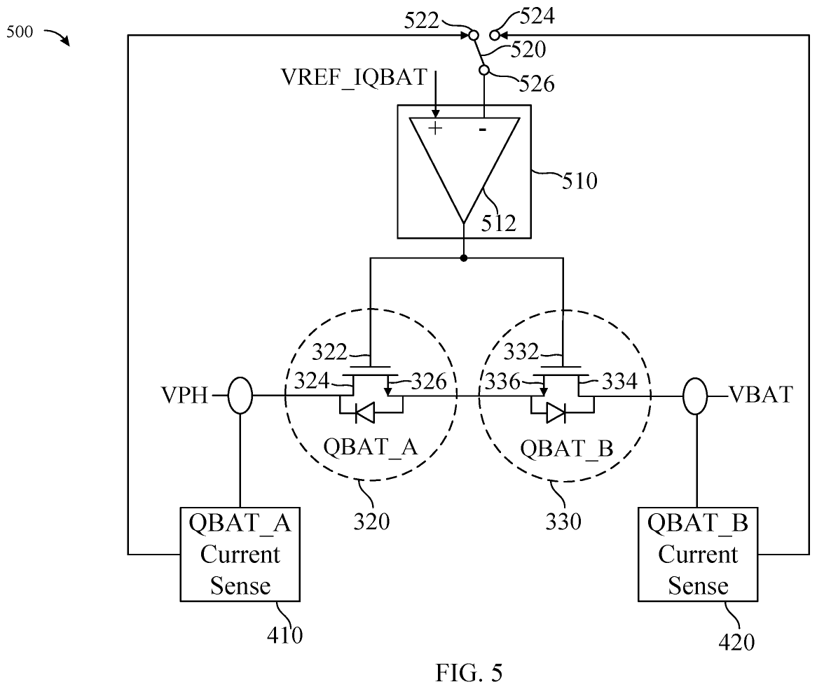

FIG. 5 depicts a portion of another example power supply circuit 500, in accordance with certain aspects of the present disclosure. The power supply circuit 500 may include the first transistor 320, the second transistor 330, the first current sense circuit 410, and the second current sense circuit 420 of the power supply circuit 400 discussed above with reference to FIG. 4A. However, the power supply circuit 500 of FIG. 5 does not include separate control circuits (e.g., the first control circuit 430 and the second control circuit 440 of the power supply circuit 400 of FIG. 4A) for the first transistor 320 and the second transistor 330. Instead, the power supply circuit 500 of FIG. 5 includes a control circuit 510 configured to control operation of both the first transistor 320 and the second transistor 330.

As shown, the control circuit 510 may include an amplifier 512. The amplifier 512 includes a first input coupled to a reference voltage node. For instance, the reference voltage node may correspond to a reference voltage (labeled “VREF_IQBAT”) for a current through the back-to-back transistors. The amplifier 512 further includes a second input that may be selectively coupled to the first current sense circuit 410 or the second current sense circuit 420 via a switching device 520. As shown, the switching device 520 includes a first terminal 522 coupled to the output of the first current sense circuit 410, a second terminal 524 coupled to the output of the second current sense circuit 420, and a common terminal 526 coupled to the second input of the amplifier 512.

The amplifier 512 further includes an output coupled to the gate 322 of the first transistor 320 and the gate 332 of the second transistor 330. In this manner, the gate 322 of the first transistor 320 and the gate 332 of the second transistor 330 may be shorted together to allow both transistors 320, 330 to be controlled by the same control signal (e.g., the output of the amplifier 512).

In operation, current sense information (e.g., V_MEASURED) output by the first current sense circuit 410 or the second current sense circuit 420 can be provided to the second input of the amplifier 512. Based on the current sense information and the reference voltage, the amplifier 512 can output a control signal to control the gate voltage of the first transistor 320 and the second transistor 330 to, for example, control a discharge current flowing from the battery (e.g., battery 306 of FIG. 3) to the power supply node VPH or vice versa.

The operation of the first transistor 320 and the second transistor 330 included in the power supply circuit 500 of FIG. 5 differs from the operation of the first transistor 320 and the second transistor 330 included in the power supply circuit 400 of FIG. 4A. More particularly, the transistors 320, 330 of the power supply circuit 400 of FIG. 4A operate in different modes from one another to accommodate different use cases, whereas the transistors 320, 330 of the power supply circuit 500 of FIG. 5 operate in the same mode (e.g., the linearly-on mode).

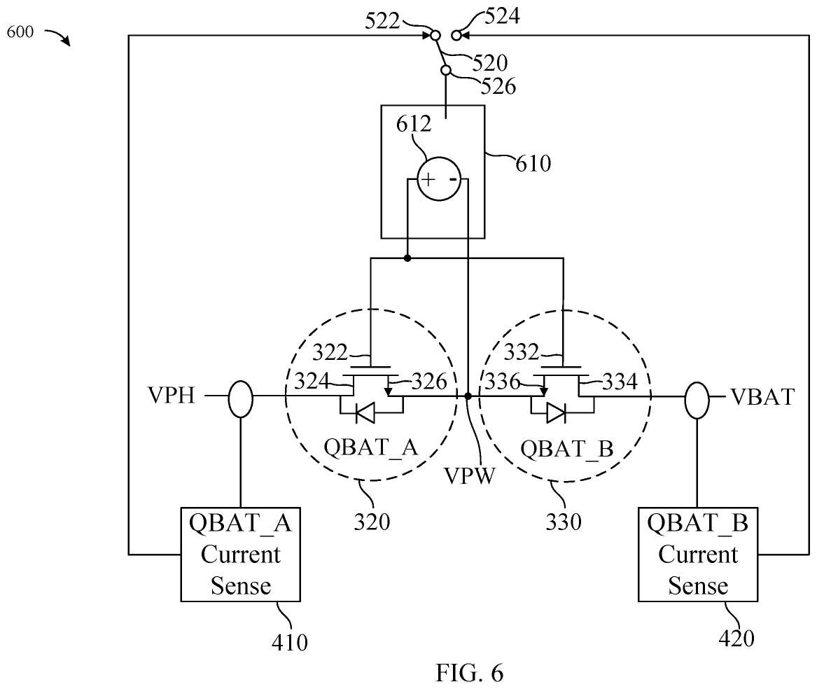

FIG. 6 depicts a portion of another example power supply circuit 600, in accordance with certain aspects of the present disclosure. The power supply circuit 600 may include the first transistor 320, the second transistor 330, the first current sense circuit 410, the second current sense circuit 420, and the switching device 520 of the power supply circuit 500 discussed above with reference to FIG. 5. However, the power supply circuit 600 of FIG. 6 may include a control circuit 610 that is different from the control circuit 510 of the power supply circuit 500 of FIG. 5. More particularly, in contrast to the control circuit 510 of FIG. 5, the control circuit 610 of FIG. 6 does not include an amplifier (e.g., the amplifier 512 of FIG. 5) having an input coupled to the switching device 520. Instead, the control circuit 610 of the power supply circuit 600 of FIG. 6 includes a constant voltage source 612, which may be independent of the sensed current.

As shown, the constant voltage source 612 may be coupled to the gate 322 of the first transistor 320 and the gate 332 of the second transistor 330. In this manner, the constant voltage source 612 is configured to apply a voltage to a gate voltage of the first transistor 320 and a gate voltage of the second transistor 330. In some aspects, as illustrated, the voltage source 612 may be coupled between the connected gates and the connected sources of the first and second transistors 320, 330. In this manner, the constant voltage source 612 may be used to apply a constant gate-to-source voltage to the first and second transistors 320, 330.

In some instances, the voltage source 612 may be implemented by a charge pump (not shown). In such instances, the voltage from the constant voltage source 612 may be a sum of a voltage generated by the charge pump and a voltage at the intermediate node VPW coupled to the sources 326, 336 of the first transistor 320 and the second transistor 330, respectively.

The operation of the first transistor 320 and the second transistor 330 included in the power supply circuit 600 of FIG. 6 differs from the operation of the first transistor 320 and the second transistor 330 included in the power supply circuit 500 of FIG. 5. More particularly, the first transistor 320 and the second transistor 330 of the power supply circuit 500 of FIG. 5 always operate in the first mode (e.g., the linearly-on mode). In contrast, the first transistor 320 and the second transistor 330 of the power supply circuit 600 of FIG. 6 always operate in the second mode (e.g., the fully-on mode) that is different from the first mode. Furthermore, since the constant voltage source 612 is not coupled to the switching device 520, the constant voltage source 612 controls the gate voltage of the first transistor 320 and the gate voltage of the second transistor 330 independent of the current flowing from the power supply node VPH to the battery node VBAT or vice versa.

### Operations for Supplying Power

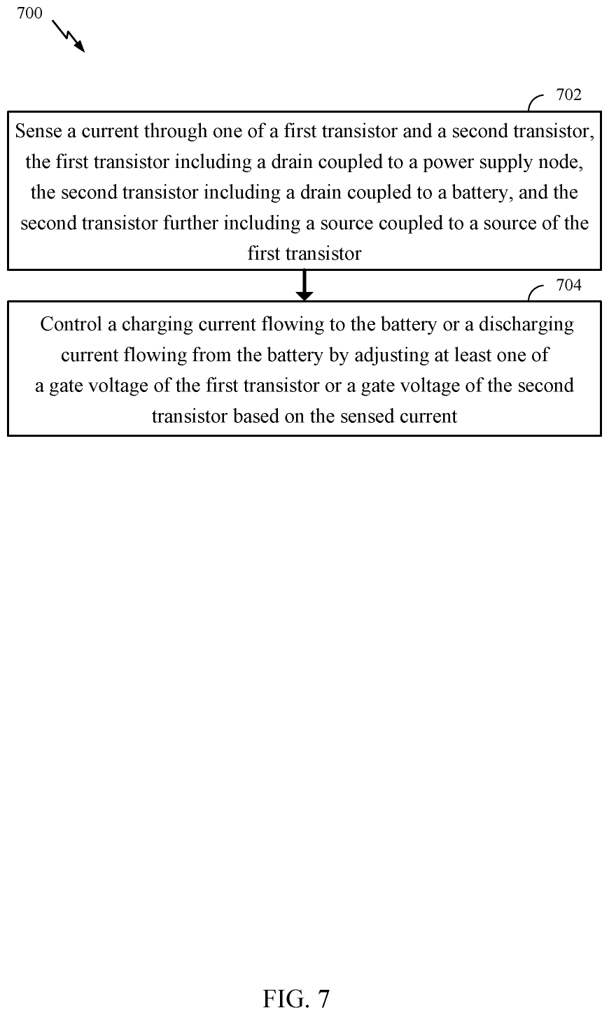

FIG. 7 is a flow diagram of example operations 700 for supplying power, in accordance with certain aspects of the present disclosure. The operations 700 may be performed by a power supply circuit (e.g., the power supply circuits 400, 500 of FIGS. 4A and 5).

The operations 700 may begin, at block 702, with sensing a current through one of a first transistor (e.g., QBAT_A) and a second transistor (e.g., QBAT_B). The first transistor QBAT_A may include a drain (e.g., drain 324) coupled to a power supply node (e.g., VPH). The second transistor QBAT_B may include a drain (e.g., drain 334) coupled to a battery node (e.g., VBAT) or to a battery (e.g., battery 306).

The operations 700 may further include, at block 704, controlling a charging current flowing to the battery or a discharging current flowing from the battery by adjusting at least one of a gate voltage of the first transistor or a gate voltage of the second transistor based on the sensed current.

Controlling the charging current may include controlling the gate voltage of the first transistor such that the first transistor operates in a first mode (e.g., a linearly-on mode). For example, controlling the gate voltage of the first transistor to operate the first transistor in the first mode may include comparing a measured voltage output by a current sense circuit coupled to the drain of the second transistor to a reference voltage and controlling the gate voltage of the first transistor based on the comparison of the measured voltage to the reference voltage. Controlling the charging current may also include controlling the gate voltage of the second transistor such that the second transistor operates in a second mode (e.g., a fully-on mode) that is different from the first mode. For example, controlling the gate voltage of the second transistor such that the second transistor operates in the second mode may include controlling the gate voltage of the second transistor with a voltage source based on a voltage at the battery or a voltage at an intermediate node coupled to the sources of the first transistor and the second transistor.

Controlling the discharging current may include controlling the gate voltage of the first transistor such that the first transistor operates in a first mode (e.g., a fully-on mode). For example, controlling the gate voltage of the first transistor to operate the first transistor in the first mode may include controlling the gate voltage of the first transistor with a voltage source based on a voltage at the battery or a voltage at an intermediate node coupled to the sources of the first transistor and the second transistor. Controlling the discharging current may also include controlling the gate voltage of the second transistor such that the second transistor operates in a second mode (e.g., a linearly-on mode). For example, controlling the gate voltage of the second transistor to operate the second transistor in the second mode may include comparing a measured voltage output by a current sense circuit coupled to the drain of the first transistor to a reference voltage and controlling the gate voltage of the second transistor based on the comparison of the measured voltage to the reference voltage.

According to certain aspects, the operations 700 may further involve disabling a first current sense circuit coupled to the drain of the first transistor while controlling the charging current. Additionally, or alternatively, the operations 700 may further involve disabling a second current sense circuit coupled to the drain of the second transistor while controlling the discharging current.

### Example Aspects

In addition to the various aspects described above, specific combinations of aspects are within the scope of the disclosure, some of which are detailed below:
Aspect 1: A power supply circuit comprising: a switching regulator including an output node coupled to a power supply node; a battery node for coupling to a battery; a first transistor including a drain coupled to the power supply node; a second transistor including a source coupled to a source of the first transistor and a drain coupled to the battery node; a first current sense circuit coupled to the drain of the first transistor; and a second current sense circuit coupled to the drain of the second transistor.
Aspect 2: The power supply circuit of Aspect 1, further comprising: a first control circuit including: at least one of a first input coupled to an output of the first current sense circuit or a second input coupled to an output of the second current sense circuit; and an output coupled to a gate of the first transistor; and a second control circuit including: at least one of a first input coupled to the output of the first current sense circuit or a second input coupled to the output of the second current sense circuit; and an output coupled to a gate of the second transistor
Aspect 3: The power supply circuit of Aspect 1, further comprising: a first control circuit configured to operate the first transistor in a first mode or a second mode that is different from the first mode; and a second control circuit configured to operate the second transistor in the first mode or the second mode.
Aspect 4: The power supply circuit of Aspect 3, wherein when a voltage at the power supply node is greater than a voltage at the battery node, the first control circuit is configured to operate the first transistor in the first mode and the second control circuit is configured to operate the second transistor in the second mode, to adjust a current flowing from the output node to the battery node.
Aspect 5: The power supply circuit of Aspect 4, wherein: the first current sense circuit is configured to be disabled; in the first mode, the first control circuit is configured to regulate a gate voltage of the first transistor based on current sense data obtained from the second current sense circuit to adjust the current; and in the second mode, the second control circuit is configured to regulate a gate voltage of the second transistor such that the gate voltage of the second transistor is constant relative to the voltage at the battery node or at an intermediate node coupled to the source of the second transistor.
Aspect 6: The power supply circuit of Aspect 3, wherein when a voltage at the power supply node is less than a voltage at the battery node, the first control circuit is configured to operate the first transistor in the second mode and the second control circuit is configured to operate the second transistor in the first mode to adjust a current flowing from the battery node to the output node.
Aspect 7: The power supply circuit of Aspect 6, wherein: the second current sense circuit is configured to be disabled; in the second mode, the first control circuit is configured to regulate a gate voltage of the first transistor such that the gate voltage of the first transistor is constant relative to the voltage at the power supply node or at an intermediate node coupled to the source of the first transistor; and in the first mode, the second control circuit is configured to regulate a gate voltage of the second transistor based on current sense data obtained via the first current sense circuit to adjust the current.
Aspect 8: The power supply circuit of Aspect 1, further comprising: a control circuit including an output coupled to a gate of the first transistor and a gate of the second transistor and a first input coupled to a reference voltage node; and a switching device including a first terminal coupled to the output of the first current sense circuit, a second terminal coupled to the output of the second current sense circuit, and a common terminal coupled to a second input of the control circuit.
Aspect 9: The power supply circuit of Aspect 1, further comprising: a control circuit including an output coupled to the first transistor and the second transistor, the control circuit configured to control operation of the first transistor and the second transistor based on current sense data obtained from the first current sense circuit or the second current sense circuit; and a switching device configured to selectively couple an input of the control circuit to an output of the first current sense circuit or an output of the second current sense circuit.
Aspect 10: The power supply circuit of Aspect 9, wherein: when a voltage at the power supply node is greater than a voltage at the battery node, the switching device is configured to couple the input of the control circuit to the output of the second current sense circuit; and when a voltage at the battery node is greater than a voltage at the power supply node, the switching device is configured to couple the input of the control circuit to the output of the first current sense circuit.
Aspect 11: The power supply circuit of Aspect 9 or 10, wherein the control circuit comprises an amplifier comprising: a first input coupled to the switching device; a second input coupled to a reference voltage node; and an output coupled to a gate of the first transistor and a gate of the second transistor.
Aspect 12: The power supply circuit of Aspect 9 or 10, wherein the control circuit comprises a constant voltage source coupled to a gate of the first transistor and a gate of the second transistor and is configured to apply a voltage from the constant voltage source to a gate voltage of the first transistor and a gate voltage of the second transistor.
Aspect 13: The power supply circuit of Aspect 12, wherein the control circuit comprises a charge pump and wherein the voltage from the constant voltage source is configured to be a sum of: a voltage at the battery node or a voltage at an intermediate node coupled to the sources of the first and second transistors; and a voltage generated by the charge pump.
Aspect 14: An integrated circuit comprising the power supply circuit according to any of Aspects 1 to 13.
Aspect 15: A device comprising: a switching regulator including an output coupled to a power supply node; a battery coupled to a battery node; a first transistor including a drain coupled to the power supply node; a second transistor including a source coupled to a source of the first transistor and a drain coupled to the battery node; a first current sense circuit coupled to the drain of the first transistor; and a second current sense circuit coupled to the drain of the second transistor.
Aspect 16: A method of supplying power comprising: sensing a current through one of a first transistor and a second transistor, the first transistor including a drain coupled to a power supply node, the second transistor including a drain coupled to a battery, and the second transistor further including a source coupled to a source of the first transistor; and controlling a charging current flowing to the battery or a discharging current flowing from the battery by adjusting a gate voltage of the first transistor and a gate voltage of the second transistor based on the sensed current.
Aspect 17: The method of Aspect 16, wherein controlling the charging current or the discharging current comprises: controlling the gate voltage of the first transistor such that the first transistor operates in a first mode; and controlling the gate voltage of the second transistor such that the second transistor operates in a second mode that is different from the first mode.
Aspect 18: The method of Aspect 17, wherein controlling the gate voltage of the first transistor such that the first transistor operates in the first mode comprises: comparing a measured voltage output by a current sense circuit coupled to the drain of the second transistor to a reference voltage; and controlling the gate voltage of the first transistor based, at least in part, on the comparing.
Aspect 19: The method of Aspect 17 or 18, wherein controlling the gate voltage of the second transistor such that the second transistor operates in the second mode comprises controlling the gate voltage of the second transistor with a voltage source based on a voltage at the battery or a voltage at an intermediate node coupled to the source of the first transistor and the source of the second transistor.
Aspect 20: The method of Aspect 16, further comprising: disabling a first current sense circuit coupled to the drain of the first transistor while controlling the charging current; and disabling a second current sense circuit coupled to the drain of the second transistor while controlling the discharging current.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A power supply circuit comprising:
a switching regulator including an output node coupled to a power supply node;
a battery node for coupling to a battery;
a first transistor including a drain coupled to the power supply node;
a second transistor including a source coupled to a source of the first transistor and a drain coupled to the battery node;
a first current sense circuit coupled to the drain of the first transistor; and
a second current sense circuit coupled to the drain of the second transistor.

2. The power supply circuit of claim 1, further comprising:
a first control circuit including:
at least one of a first input coupled to an output of the first current sense circuit or a second input coupled to an output of the second current sense circuit; and
an output coupled to a gate of the first transistor; and
a second control circuit including:
at least one of a first input coupled to the output of the first current sense circuit or a second input coupled to the output of the second current sense circuit; and
an output coupled to a gate of the second transistor.

3. The power supply circuit of claim 1, further comprising:
a first control circuit configured to operate the first transistor in a first mode or a second mode that is different from the first mode; and
a second control circuit configured to operate the second transistor in the first mode or the second mode.

4. The power supply circuit of claim 3, wherein when a voltage at the power supply node is greater than a voltage at the battery node, the first control circuit is configured to operate the first transistor in the first mode and the second control circuit is configured to operate the second transistor in the second mode, to adjust a current flowing from the output node to the battery node.

5. The power supply circuit of claim 4, wherein:
the first current sense circuit is configured to be disabled;
in the first mode, the first control circuit is configured to regulate a gate voltage of the first transistor based on current sense data obtained from the second current sense circuit to adjust the current; and
in the second mode, the second control circuit is configured to regulate a gate voltage of the second transistor such that the gate voltage of the second transistor is constant relative to the voltage at the battery node or at an intermediate node coupled to the source of the second transistor.

6. The power supply circuit of claim 3, wherein when a voltage at the power supply node is less than a voltage at the battery node, the first control circuit is configured to operate the first transistor in the second mode and the second control circuit is configured to operate the second transistor in the first mode to adjust a current flowing from the battery node to the output node.

7. The power supply circuit of claim 6, wherein:
the second current sense circuit is configured to be disabled;
in the second mode, the first control circuit is configured to regulate a gate voltage of the first transistor such that the gate voltage of the first transistor is constant relative to the voltage at the power supply node or at an intermediate node coupled to the source of the first transistor; and
in the first mode, the second control circuit is configured to regulate a gate voltage of the second transistor based on current sense data obtained via the first current sense circuit to adjust the current.

8. The power supply circuit of claim 1, further comprising:
a control circuit including an output coupled to a gate of the first transistor and a gate of the second transistor and a first input coupled to a reference voltage node; and
a switching device including a first terminal coupled to the output of the first current sense circuit, a second terminal coupled to the output of the second current sense circuit, and a common terminal coupled to a second input of the control circuit.

9. The power supply circuit of claim 1, further comprising:
a control circuit including an output coupled to the first transistor and the second transistor, the control circuit configured to control operation of the first transistor and the second transistor based on current sense data obtained from the first current sense circuit or the second current sense circuit; and
a switching device configured to selectively couple an input of the control circuit to an output of the first current sense circuit or an output of the second current sense circuit.

10. The power supply circuit of claim 9, wherein:
when a voltage at the power supply node is greater than a voltage at the battery node, the switching device is configured to couple the input of the control circuit to the output of the second current sense circuit; and
when a voltage at the battery node is greater than a voltage at the power supply node, the switching device is configured to couple the input of the control circuit to the output of the first current sense circuit.

11. The power supply circuit of claim 9, wherein the control circuit comprises an amplifier comprising:
a first input coupled to the switching device;
a second input coupled to a reference voltage node; and
an output coupled to a gate of the first transistor and a gate of the second transistor.

12. The power supply circuit of claim 9, wherein the control circuit comprises a constant voltage source coupled to a gate of the first transistor and a gate of the second transistor and is configured to apply a voltage from the constant voltage source to a gate voltage of the first transistor and a gate voltage of the second transistor.

13. The power supply circuit of claim 12, wherein the control circuit comprises a charge pump and wherein the voltage from the constant voltage source is configured to be a sum of:
a voltage at the battery node or a voltage at an intermediate node coupled to the sources of the first and second transistors; and
a voltage generated by the charge pump.

14. An integrated circuit comprising the power supply circuit of claim 1.

15. A device comprising:
a switching regulator including an output coupled to a power supply node;
a battery coupled to a battery node;
a first transistor including a drain coupled to the power supply node;
a second transistor including a source coupled to a source of the first transistor and a drain coupled to the battery node;
a first current sense circuit coupled to the drain of the first transistor; and
a second current sense circuit coupled to the drain of the second transistor.

16. A method of supplying power, comprising:
sensing a current through one of a first transistor and a second transistor, the first transistor including a drain coupled to a power supply node, the second transistor including a drain coupled to a battery, and the second transistor further including a source coupled to a source of the first transistor; and
controlling a charging current flowing to the battery or a discharging current flowing from the battery by adjusting a gate voltage of the first transistor and a gate voltage of the second transistor based on the sensed current.

17. The method of claim 16, wherein controlling the charging current or the discharging current comprises:
controlling the gate voltage of the first transistor such that the first transistor operates in a first mode; and
controlling the gate voltage of the second transistor such that the second transistor operates in a second mode that is different from the first mode.

18. The method of claim 17, wherein controlling the gate voltage of the first transistor such that the first transistor operates in the first mode comprises:
comparing a measured voltage output by a current sense circuit coupled to the drain of the second transistor to a reference voltage; and
controlling the gate voltage of the first transistor based, at least in part, on the comparing.

19. The method of claim 17, wherein controlling the gate voltage of the second transistor such that the second transistor operates in the second mode comprises controlling the gate voltage of the second transistor with a voltage source based on a voltage at the battery or a voltage at an intermediate node coupled to the source of the first transistor and the source of the second transistor.

20. The method of claim 16, further comprising:
disabling a first current sense circuit coupled to the drain of the first transistor while controlling the charging current; and
disabling a second current sense circuit coupled to the drain of the second transistor while controlling the discharging current.
